(19) United States
(12) Patent Application Publication
(10) Pub. No.: US 2014/0184003 A1
(43) Pub. Date: Jul. 3, 2014

(54) SYSTEMS AND METHODS FOR ROTATIONAL ALIGNMENT OF A DEVICE UNDER TEST

(71) Applicant: CASCADE MICROTECH, INC., BEAVERTON, OR (US)

(72) Inventors: Jorg Kiesewetter, Thiendorf OT Sacka (DE); Karsten Stoll, Sohland an der Spree (DE)

(73) Assignee: CASCADE MICROTECH, INC., BEAVERTON, OR (US)

(21) Appl. No.: 14/141,749

(22) Filed: Dec. 27, 2013

Related U.S. Application Data
(60) Provisional application No. 61/747,628, filed on Dec. 31, 2012.

(51) Int. Cl. H02K 7/08; G01R 1/067

(52) U.S. Cl. CPC H02K 7/08; G01R 1/067
USPC 310/90; 324/754.03; 324/750.14

(57) ABSTRACT

Systems and methods for rotational alignment of a device under test are disclosed herein. These systems include a chuck that includes a rotational positioning assembly that includes a lower section and an upper section that is configured to selectively rotate relative to the lower section about a rotational axis. The rotational positioning assembly further includes a first bearing that is configured to support a radial load between the upper section and the lower section and a second bearing that is configured to support a thrust load between the upper section and the lower section. The methods include providing a fluid stream to the second bearing to permit rotation of the upper section relative to the lower section, rotating the upper section relative to the lower section, and ceasing the providing the fluid stream to the second bearing to restrict rotation of the upper section relative to the lower section.

### RELATED APPLICATION

This application claims priority to U.S. Provisional Patent Application No. 61/747,628, which was filed on Dec. 31, 2012, and the complete disclosure of which is hereby incorporated by reference.

### FIELD OF THE DISCLOSURE

The present disclosure is directed generally to systems and methods for rotational alignment of a device under test and more particularly to systems and methods that utilize a rotational positioning assembly including a first bearing that is configured to support an axial load and a second bearing that is configured to support a thrust load.

### BACKGROUND OF THE DISCLOSURE

Probe systems for contacting and testing a device under test (DUT) may include and/or utilize a rotational positioning assembly to rotationally align the DUT with one or more probe tips of the probe system. This may include rotating a chuck, which supports the DUT and forms a portion of the probe system. Generally, the chuck is configured to provide a rigid surface for support of the DUT, with this rigid surface not deflecting when contact is established between the one or more probe tips and the DUT. The required rigidity increases as the overall contact force between the one or more probe tips and the DUT increases (such as may be due to an increased number of probe tips contacting the DUT) and/or as a contact area for the one or more probe tips on the DUT decreases (such as may be due to decreased dimension of a contact pad on an upper surface of the DUT).

Historically, this rigidity has been obtained by utilizing a large-diameter rotary bearing to provide for a rotational motion that may be needed to establish the rotational alignment between the DUT and the corresponding probe tips of the probe system. However, and while such a large-diameter rotary bearing may provide the desired level of rigidity, the large-diameter rotary bearing also requires a large torsional force, or torque, to produce the rotational motion, may have a large amount of internal friction, and/or may be subject to stick-slip motion, especially when rotated over short distances. These limitations may interfere with the use of large-diameter rotary bearings in high-precision test systems that are to be utilized with DUTs that include small contact areas. Thus, there exists a need for improved systems and methods for rotational alignment of a device under test.

### SUMMARY OF THE DISCLOSURE

Systems and methods for rotational alignment of a device under test are disclosed herein. These systems may include a chuck that includes a rotational positioning assembly that includes a lower section and an upper section that is configured to selectively rotate relative to the lower section about a rotational axis. The rotational positioning assembly further includes a first bearing, which is configured to support a radial load between the upper section and the lower section, and a second bearing, which is configured to support a thrust load between the upper section and the lower section.

In some embodiments, the first bearing and/or the second bearing are configured to permit translation of the upper section relative to the lower section along the rotational axis. In some embodiments, the first bearing includes a rolling element bearing. In some embodiments, the first bearing is operatively attached to the lower section and to the upper section.

In some embodiments, the first bearing includes a first fluid bearing. In some embodiments, the first bearing is defined by a first radial load-bearing surface and a second radial load-bearing surface. In some embodiments, the assembly further includes a first fluid distribution manifold that is configured to provide a first fluid stream to a first fluid gap that may be defined between the first radial load-bearing surface and the second radial load-bearing surface.

In some embodiments, the second bearing includes a second fluid bearing. In some embodiments, the second bearing is defined by a first thrust load-bearing surface and a second thrust load-bearing surface. In some embodiments, the rotational positioning assembly further includes a second fluid distribution manifold that is configured to selectively provide a second fluid stream to a second fluid gap that may be defined between the first thrust load-bearing surface and the second thrust load-bearing surface. In some embodiments, the second bearing is configured to permit rotation of the upper section relative to the lower section about the rotational axis when the second fluid stream is provided to the second fluid gap.

In some embodiments, the second fluid distribution manifold is configured to selectively provide a vacuum to the second bearing. In some embodiments, at least a portion of the first thrust load-bearing surface is configured to contact at least a portion of the second thrust load-bearing surface when the vacuum is provided to the second bearing. In some embodiments, the second bearing is configured to resist rotation of the upper section relative to the lower section about the rotational axis when the vacuum is provided to the second bearing.

In some embodiments, the rotational positioning assembly further includes a rotational drive that is configured to selectively provide a motive force for rotation of the upper section relative to the lower section. In some embodiments, the systems further may include a chuck that includes a chuck body that is operatively attached to the rotational positioning assembly. In some embodiments, the systems include a test system that includes a probe and the chuck. In some embodiments, the test system further includes an enclosure, a probe card, a signal generation assembly, and/or a signal analysis assembly.

The methods may include providing a fluid stream to the second bearing to permit rotation of the upper section relative to the lower section, rotating the upper section relative to the lower section, and ceasing the providing the fluid stream to the second bearing to restrict rotation of the upper section relative to the lower section. In some embodiments, the providing may include establishing the fluid gap between the first thrust load-bearing surface and the second thrust load-bearing surface. In some embodiments, the ceasing may include establishing physical contact between the first thrust load-bearing surface and the second thrust load-bearing surface.

### BRIEF DESCRIPTION OF THE DRAWINGS

FIG. 1 is a schematic representation of illustrative, non-exclusive examples of a probe system according to the present disclosure.

FIG. 2 is a schematic representation of illustrative, non-exclusive examples of a rotational positioning assembly according to the present disclosure.

FIG. 3 is a schematic cross-sectional view of illustrative, non-exclusive examples of a rotational positioning assembly according to the present disclosure with an air gap between a lower section and an upper section thereof.

FIG. 4 is a schematic cross-sectional view of the rotational positioning assembly of FIG. 3 without the air gap between the lower section and the upper section.

FIG. 5 is a less schematic cross-sectional view of illustrative, non-exclusive examples of a rotational positioning assembly according to the present disclosure.

FIG. 6 is a detail view of a portion of the rotational positioning assembly of FIG. 5.

FIG. 7 is a top view of the rotational positioning assembly of FIG. 5.

FIG. 8 is a flowchart depicting methods according to the present disclosure of rotating a chuck within a probe system and/or of testing a device under test.

### DETAILED DESCRIPTION AND BEST MODE OF THE DISCLOSURE

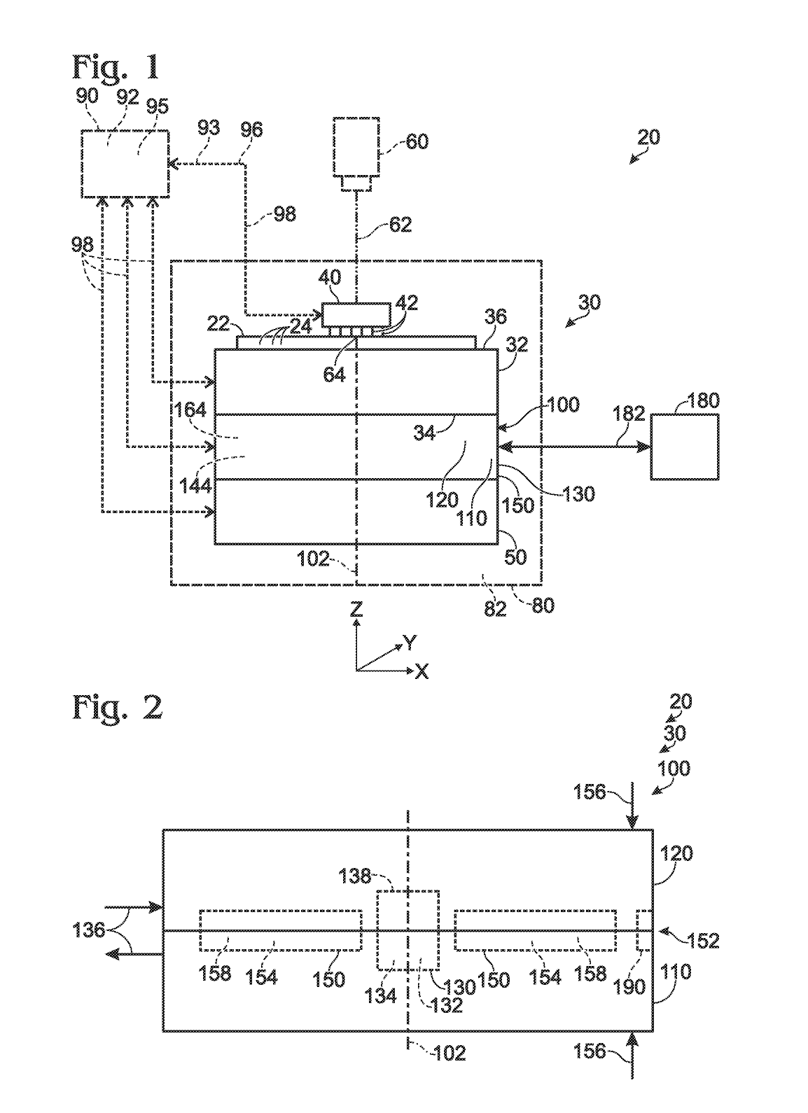

FIGS. 1-7 provide illustrative, non-exclusive examples of probe systems 20, rotational positioning assemblies 100, and/or components thereof according to the present disclosure. Elements that serve a similar, or at least substantially similar, purpose and/or function are labeled with like numbers in FIGS. 1-7, and these elements may not be discussed in detail herein with reference to each of FIGS. 1-7. Similarly, all elements may not be labeled in each of FIGS. 1-7, but reference numerals associated therewith may still be utilized herein for consistency. In addition, and while each of FIGS. 1-7 illustrate specific aspects of probe systems 20, rotational positioning assemblies 100, and/or components thereof according to the present disclosure, any component and/or feature that is discussed herein with reference to any one of FIGS. 1-7 may be utilized with any other of FIGS. 1-7 without departing from the scope of the present disclosure.

In general, elements that are likely to be included in a given embodiment are shown in solid lines, while elements that are optional to a given embodiment are shown in dashed lines. However, elements that are shown in solid lines are not essential to all embodiments, and an element shown in solid lines may be omitted from a particular embodiment without departing from the scope of the present disclosure.

FIG. 1 is a schematic representation of illustrative, non-exclusive examples of a probe system 20 according to the present disclosure. Probe system 20 includes a chuck 30 that defines an upper surface 36. Upper surface 36 is configured to support and/or be in contact (such as electrical and/or mechanical contact) with a substrate 22 that includes a plurality of devices under test (DUTs) 24. Probe system 20 further includes a probe card 40 that includes a plurality of probe tips 42. Probe tips 42 are configured to form a plurality of connections with at least one of the devices under test. Probe system 20 also may include a control system 90 that may be adapted, configured, and/or programmed to control the operation of the probe system and/or an enclosure 80 that is sized and/or configured to contain substrate 22 and at least a portion of chuck 30.

Chuck 30 may be, include, be operatively attached to, and/or be in mechanical communication with any suitable structure that may support substrate 22 and/or locate substrate 22 relative to probe tips 42. As an illustrative, non-exclusive example, chuck 30 may include a chuck body 32 that may define upper surface 36 and a lower surface 34. It is within the scope of the present disclosure that chuck 30 and/or chuck body 32 thereof may include and/or be an electrostatic chuck, a vacuum chuck, a thermal chuck, and/or a temperature-controlled chuck.

Chuck 30 further may include (and/or chuck body 32 may be operatively attached to and/or in mechanical communication with) a rotational positioning assembly 100. Rotational positioning assembly 100 may be configured to permit, produce, generate, and/or cause selective rotation of chuck body 32, and thus substrate 22 and/or DUTs 24, relative to probe tips 42 about a rotational axis 102. FIGS. 2-7 provide additional illustrative, non-exclusive examples of rotational positioning assembly 100 and/or components thereof, and any of the rotational positioning assemblies of any of FIGS. 2-7 may be utilized with probe system 20 of FIG. 1 without departing from the scope of the present disclosure.

As discussed in more detail herein with reference to FIGS. 2-7, rotational positioning assembly 100 may include a lower section 110 and an upper section 120 that is configured to selectively rotate relative to the lower section about rotational axis 102. The rotational positioning assembly further may include a first bearing 130, which is configured to support a radial load between the upper section and the lower section when the upper section rotates relative to the lower section, and a second bearing 150, which is configured to support a thrust load between the upper section and the lower section when the upper section rotates relative to the lower section. The radial load may be at least substantially perpendicular to, and optionally may be perpendicular to, the thrust load.

As also discussed with reference to FIGS. 2-7, first bearing 130 and/or second bearing 150 may include and/or be fluid bearings. As such, probe system 20 further may include a fluid transfer assembly 180 (as illustrated in FIG. 1) that may be configured to provide a fluid stream 182 to the fluid bearings (i.e., pressurize the fluid bearings) and/or remove the fluid stream from the fluid bearings (i.e., depressurize and/or apply a vacuum to the fluid bearings). When the fluid stream is supplied to first bearing 130, the first bearing may define a first fluid gap 144. Similarly, and when the fluid stream is supplied to second bearing 150, the second bearing may define a second fluid gap 164. Fluid gaps 144/164 are discussed in more detail herein.

Returning to FIG. 1, chuck 30 further may include (and/or chuck body 32 may be operatively attached to and/or in mechanical communication with) a translational positioning assembly 50. Translational positioning assembly 50 may be configured to permit, produce, generate, and/or cause selective translation of chuck body 32, and thus substrate 22 and/or DUTs 24, relative to probe tips 42. This may include translation along rotational axis 102 (e.g., translation in a vertical direction and/or in a Z-direction) and/or translation along one or more directions that may be perpendicular to rotational axis 102 (e.g., translation in a horizontal direction, in an X-direction, and/or in a Y-direction).

Translational positioning assembly 50 may include any suitable structure that may permit translation of chuck body 32 relative to probe tips 42. As illustrative, non-exclusive examples, the translational positioning assembly may include one or more translation stages, linear translation stages, horizontal translation stages, vertical translation stages, gear-driven translation stages, ball screws, threaded rods, nuts, stepper motors, and/or piezoelectric positioning devices.

As discussed, control system 90 may be programmed to control the operation of at least a portion of probe system 20. As an illustrative, non-exclusive example, control system 90 may be programmed to provide one or more control signals 98 to chuck 30, to chuck body 32, to probe card 40, to rotational positioning assembly 100, and/or to translational positioning assembly 50. This may include controlling a relative orientation of upper surface 36 of chuck 30, and thus a relative orientation of substrate 22 and/or DUTs 24, with respect to probe tips 42 and/or controlling a distance between upper surface 36 and probe tips 42. Additionally or alternatively, this also may include controlling a temperature of chuck body 32.

As another illustrative, non-exclusive example, control system 90 may be programmed to perform and/or execute methods 200, which are discussed in more detail herein. As yet another illustrative, non-exclusive example, control system 90 may include a signal generation assembly 92 that may be configured to provide one or more test signals 93 to DUTs 24. DUTs 24 may receive the one or more test signals from the signal generation assembly and may produce one or more resultant signals 96 therefrom. Probe system 20 may provide resultant signals 96 to control system 90, such as to a signal analysis assembly 95 thereof. Test signals 93 additionally or alternatively may be referred to as input signals 93 and/or probe signals 93. Resultant signals 96 may additionally or alternatively be referred to as output signals 96 and/or DUT signals 96.

Illustrative, non-exclusive examples of signal generation assemblies 92 that may be utilized with and/or included in the systems and methods according to the present disclosure include any suitable electrical power source, voltage generator, electric current generator, and/or function generator. Illustrative, non-exclusive examples of signal analysis assemblies 95 that may be utilized with and/or included in the systems and methods according to the present disclosure include any suitable impedance analyzer, network analyzer, bit error rate tester, and/or spectrum analyzer.

As illustrated in dashed lines in FIG. 1, probe system 20 further may include an imaging device 60. Imaging device 60 may be configured to collect one or more optical images of any suitable portion of probe system 20, substrate 22, and/or DUTs 24. Illustrative, non-exclusive examples of imaging device 60 include any suitable optical imaging device, microscope, camera, and/or charge-coupled device.

Imaging device 60 may define an optical axis 62 that may extend between the imaging device and a focal point 64 of the imaging device. Focal point 64 may be defined within and/or may be referred to herein as a focal plane 64 of imaging device 60. Operation of rotational positioning assembly 100 may include translation of substrate 22 and/or of DUTs 24 thereof relative to focal point 64. This may include translation of a given point (or selected portion) of a given DUT 24 into and/or out of a field of view of imaging device 60 and/or into and/or out of focus when imaged by imaging device 60.

As an illustrative, non-exclusive example, creation of a fluid gap (such as subsequently discussed second fluid gap 164) within rotational positioning assembly 100 may translate upper section 120 toward imaging device 60, thereby translating substrate 22 and/or DUTs 24 thereof toward imaging device 60 and moving DUTs 24 relative to focal plane 64. As another illustrative, non-exclusive example, rotation of substrate 22 about rotational axis 102 may cause DUTs 24 to translate relative to optical axis 62 and/or focal point 64, such as may be due to a finite misalignment between rotational axis 102 and optical axis 62, which may move the selected portion of the DUT into and/or out of the field of view of imaging device 60. Thus, and as discussed in more detail herein with reference to methods 200, the systems and methods according to the present disclosure may be configured to adjust, or even automatically adjust, to account for this translation.

Enclosure 80 may include any suitable structure that may be sized, selected, and/or configured to contain, retain, and/or otherwise house substrate 22 and/or at least a portion of chuck 30. As illustrative, non-exclusive examples, enclosure 80 may be configured to electrically, optically, fluidly, and/or electromagnetically isolate substrate 22 and/or DUTs 24 from an ambient environment that may be external to an internal volume 82 that may be defined by the enclosure.

Probe card 40, and/or probe tips 42 thereof, may include any suitable structure that is configured to form the plurality of connections with one or more DUTs 24. It is within the scope of the present disclosure that the plurality of connections may include any suitable connection that may permit any suitable form of communication between the probe tips and the one or more DUTs. As illustrative, non-exclusive examples, the plurality of connections may include a plurality of electrical, mechanical, physical, optical, and/or electromagnetic connections. Illustrative, non-exclusive examples of probe card 40 and/or probe tips 42 thereof include any suitable needle probe, pyramid probe, membrane probe, space transformer, interposer, and/or electrical conduit.

Fluid transfer assembly 180 may include any suitable structure that may be configured to provide the fluid stream to rotational positioning assembly 100 and/or to remove the fluid stream from the rotational positioning assembly. As illustrative, non-exclusive examples, fluid transfer assembly 180 may include and/or be any suitable pump, compressor, blower, vacuum pump, venturi pump, air source, and/or vacuum source. Thus, fluid transfer assembly 180 also may be referred to herein as a fluid source 180 and/or as a vacuum source 180.

Fluid stream 182 may include and/or be any suitable fluid stream. As illustrative, non-exclusive examples, fluid stream 182 may include, be, and/or be referred to herein as a liquid stream 182, a gas stream 182, and/or an air stream 182. When fluid stream 182 is a liquid stream 182, the liquid stream may be formed from a single liquid composition or may include a plurality of liquids having different compositions. When fluid stream 182 is a gas stream 182, the gas stream may be formed from a single gas composition or may include a plurality of gases having different compositions. When fluid stream 182 is an air stream 182, the air stream may be formed substantially from air, entirely from air, and/or from treated air. Treated air may include purified air, air in which at least one component has been reduced or removed, and/or air containing one or more minority concentrations of an additive or other gas.

DUTs 24 may include any suitable structure that is configured to be contacted by, electrically contacted by, mechanically contacted by, optically contacted by, and/or tested by probe system 20. As illustrative, non-exclusive examples, DUTs 24 may include and/or be any suitable integrated circuit, semiconductor device, electronic device, microelectronic mechanical system, optoelectronic device, and/or optical device.

Similarly, substrate 22 may include any suitable structure that may include, contain, and/or have formed thereon DUTs 24. As illustrative, non-exclusive examples, substrate 22 may include and/or be any suitable wafer, semiconductor wafer, silicon wafer, and/or group III-V semiconductor wafer.

For simplicity, probe system 20 is discussed herein as contacting DUTs 24 and optionally as testing the DUTs. However, it is within the scope of the present disclosure that probe system 20 may be configured to physically, mechanically, optically, and/or electrically contact (or form a physical, mechanical, optical, and/or electrical communication with) DUTs 24. Similarly, it is also within the scope of the present disclosure that the probe system may be configured to mechanically, optically, and/or electrically test one or more of the DUTs 24.

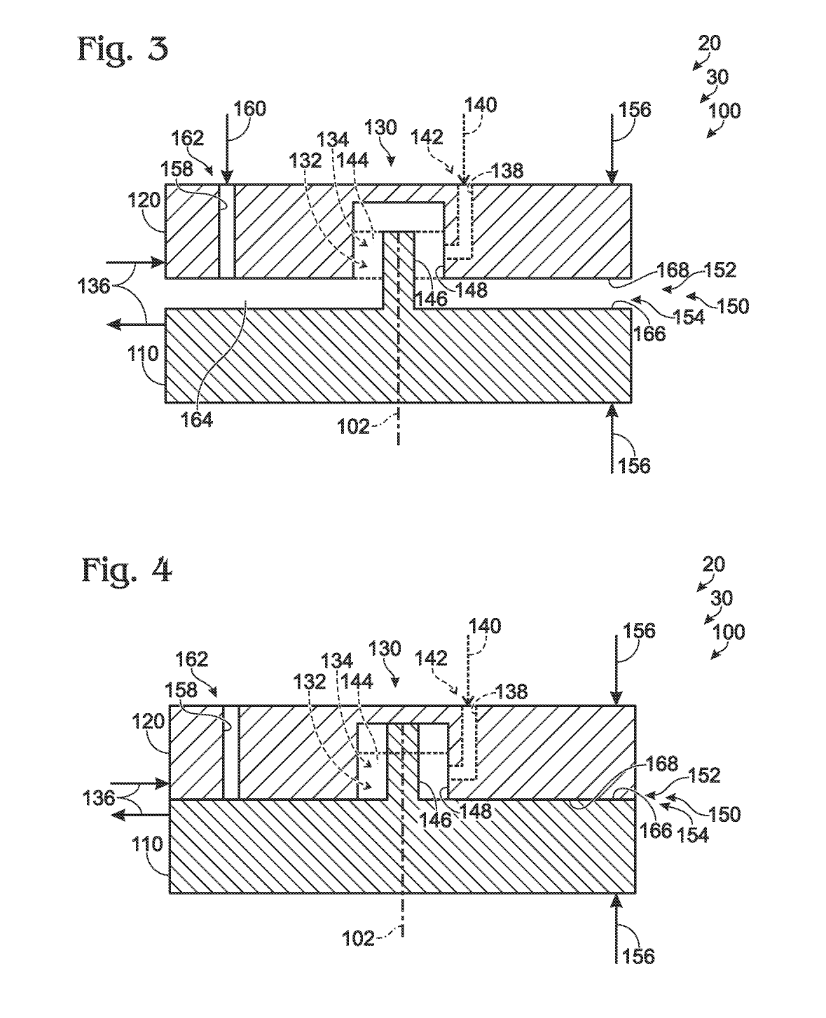

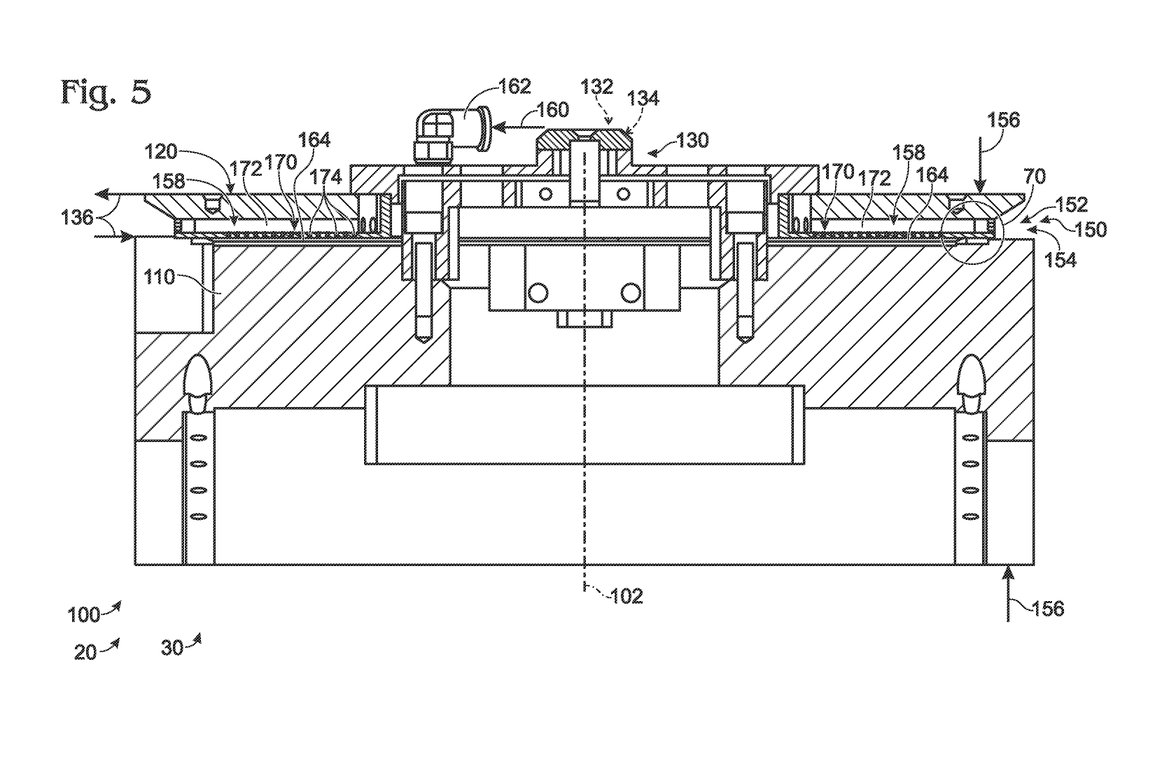

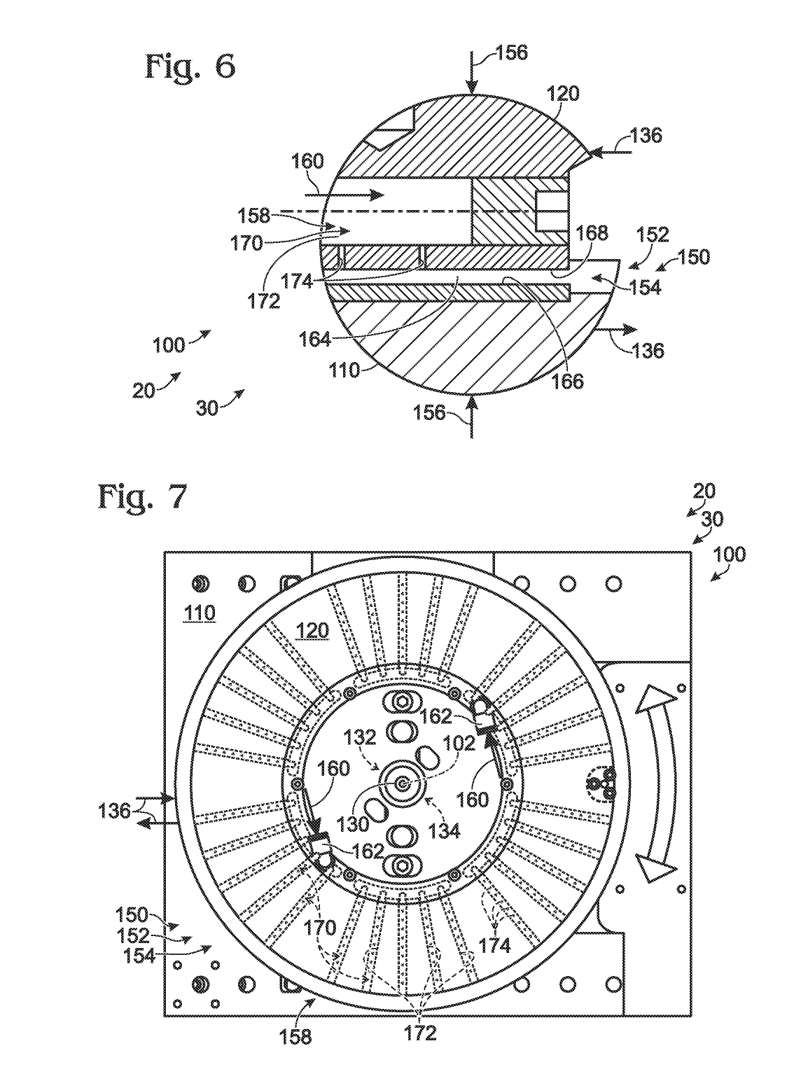

FIGS. 2-7 provide illustrative, non-exclusive examples of rotational positioning assemblies 100 according to the present disclosure, which may form a portion of and/or be utilized with chuck 30 and/or probe system 20 of FIG. 1. FIG. 2 is a schematic representation of rotational positioning assemblies 100, and FIGS. 3-4 are schematic cross-sectional views of less schematic but still illustrative, non-exclusive examples of rotational positioning assemblies 100. FIGS. 5-7 provide even less schematic views of a rotational positioning assembly 100 according to the present disclosure, with FIG. 5 providing a cross-sectional view of the rotational positioning assembly, FIG. 6 providing a more detailed view of the rotational positioning assembly of FIG. 5, and FIG. 7 providing a top view of the rotational positioning assembly of FIG. 5.

The rotational positioning assemblies 100 of FIGS. 2-7 include a lower section 110 and an upper section 120 that is configured to rotate relative to the lower section about a rotational axis 102. The rotational positioning assemblies 100 further include a first bearing 130, which is configured to support a radial load 136 between the upper section and the lower section when the upper section rotates relative to the lower section, and a second bearing 150, which is configured to support a thrust load 156 between the upper section and the lower section when the upper section rotates relative to the lower section. In addition, rotational positioning assemblies 100 also may include a rotational drive 190 (as illustrated in FIG. 2) that is configured to selectively provide a motive force, or torque, for the rotation of upper section 120 relative to lower section 110.

As discussed herein, rotational positioning assembly 100 includes first bearing 130 and second bearing 150. Traditionally, and as discussed, rotation of chuck 30 may be accomplished using a single, large-diameter rotary bearing. Such a large-diameter rotary bearing may be effective at providing a desired level of rigidity to chuck 30 and/or may support both radial load 136 and thrust load 156. However, a torque that may be needed to initiate and/or maintain motion of the large-diameter rotary bearing may be significant. In addition, an internal friction within the large-diameter rotary bearing also may be significant, and this internal friction may result in a significant amount of hysteresis and/or in stick-slip motion (e.g., spontaneous, irregular, and/or periodic variation in frictional forces) when the large-diameter rotary bearing is rotated.

In general, it may be desirable to decrease the frictional forces that are experienced when rotating upper section 120 and/or to decrease the torsional force that is needed to rotate the upper section, while also maintaining at least a threshold level of overall rigidity between upper section 120 and lower section 110 and ensuring support of both radial load 136 and thrust load 156. With this in mind, and as discussed, the systems and methods disclosed herein utilize separate bearings to support the radial and thrust loads that may be experienced during rotation of the chuck body. This separation of the radial and thrust loads may permit design, selection, and/or sizing of first bearing 130 and/or second bearing 150 to support the respective radial and thrust loads that will be experienced during rotation of rotational positioning assembly 100, while decreasing the torque that may be needed to rotate the rotational positioning assembly and/or decreasing the internal frictional forces within the rotational positioning assembly.

In FIG. 2, first bearing 130, second bearing 150, and rotational drive 190 are illustrated in dashed lines to indicate that they may be present in, operatively attached to, and/or form a portion of any suitable portion of rotational drive assembly 100. As illustrative, non-exclusive examples, at least one of the first bearing, the second bearing, and the rotational drive may be present in, operatively attached to, and/or form a portion of lower section 110. As another illustrative, non-exclusive example, at least one of the first bearing, the second bearing, and the rotational drive may be present in, operatively attached to, and/or form a portion of upper section 120. As yet another illustrative, non-exclusive example, at least one of the first bearing, the second bearing, and the rotational drive may be present in, operatively attached to, and/or form a portion of both lower section 110 and upper section 120.

In FIGS. 3-7, first bearing 130 is illustrated as being operatively attached to and/or formed by a portion of lower section 110 and a portion of upper section 120, with the portion of lower section 110 projecting from a remainder of lower section 110, and with the portion of upper section 120 being defined by a recess within the upper section. In addition, second bearing 150 is illustrated as being defined by, or at, an interface 152 between the lower section and the upper section.

First bearing 130 may include any suitable structure. As an illustrative, non-exclusive example, first bearing 130 may include and/or be a first rotary bearing 132, which also may be referred to herein as a first rolling bearing 132 and/or as a first rolling element bearing 132. Thus, first bearing 130 may include a plurality of rolling elements, a plurality of ball bearings, and/or a plurality of roller bearings.

When first bearing 130 includes first rotary bearing 132, the first bearing may be operatively attached to both lower section 110 and upper section 120, such as to first radial load-bearing surface 146 and to a second radial load-bearing surface 148 thereof (as illustrated in FIGS. 3-4). Additionally or alternatively, the first rotary bearing also may be referred to herein as operatively attaching lower section 110 to upper section 120 (as illustrated in FIGS. 3-7). Since the first bearing is not utilized to support thrust load 156 (or at least the entire thrust load), a size, or diameter, of the first rotary bearing may be significantly less than a size of the large-diameter rotary bearing that is discussed above with reference to traditional rotary positioning assemblies. Thus, the internal friction that may be present within the first rotary bearing and/or the friction force that may be needed to rotate the first rotary bearing may be significantly less than that of the large-diameter rotary bearing that is discussed above.

As another illustrative, non-exclusive example, first bearing 130 may include and/or be a first fluid bearing 134, which also may be referred to herein as and/or may be a first hydrostatic bearing 134 and/or a first air bearing 134. Once again, the internal friction that may be present within the first fluid bearing and/or the friction force that may be needed to rotate the first fluid bearing may be less, and potentially significantly less, than that of the large-diameter rotary bearing that is discussed above.

When rotational positioning assembly 100 includes first fluid bearing 134, the assembly further may include a first fluid distribution manifold 138. As illustrated in FIGS. 3-4, first fluid distribution manifold 138 may be configured to provide a first fluid stream 140 (such as from fluid transfer assembly 180 of FIG. 1) from a first fluid inlet 142 to a first fluid gap 144 of first fluid bearing 134. First fluid gap 144 may be defined between first radial load-bearing surface 146, which may be defined by lower section 110, and second radial load-bearing surface 148, which may be defined by upper section 120.

When first fluid stream 140 is provided to first fluid gap 144, a fluid pressure may develop therein. This fluid pressure may provide a motive force that may resist contact between first radial load-bearing surface 146 and second radial load-bearing surface 148, and a magnitude of the motive force may be proportional to the fluid pressure, the surface area of the first radial load-bearing surface, and/or the surface area of the second radial load-bearing surface. Thus, first radial load-bearing surface 146 and/or second radial load-bearing surface 148 may be sized to prevent contact therebetween when first fluid stream 140 is supplied to first fluid distribution manifold 138 and a magnitude of radial load 136 is less than a threshold radial load magnitude.

Returning generally to FIGS. 2-7, second bearing 150 may include and/or be a second fluid bearing 154, which also may be referred to herein as a second hydrostatic bearing 154 and/or as a second air bearing 154. As such, second fluid bearing 154 may not be, and/or may not include, a rotary bearing, a rolling bearing, and/or a rolling element bearing.

As illustrated in FIGS. 3-4 and 6, second fluid bearing 154 may be defined by a first thrust load-bearing surface 166, which may be defined by lower section 110, and a second thrust load-bearing surface 168, which may be defined by upper section 120. As illustrated in FIGS. 3-4, first thrust load-bearing surface 166 may be at least substantially perpendicular to first radial load-bearing surface 146. Similarly, second thrust load-bearing surface 168 may be at least substantially perpendicular to second radial load-bearing surface 148.

When second bearing 150 includes second fluid bearing 154, rotational positioning assembly 100 further may include a second fluid distribution manifold 158. As illustrated in FIGS. 3 and 5, second fluid distribution manifold 158 may be configured to selectively provide a second fluid stream 160 (such as from fluid transfer assembly 180 of FIG. 1) from a second fluid inlet 162 to a second fluid gap 164 of second fluid bearing 154. As illustrated in FIGS. 3 and 4, second fluid gap 164 may be defined between first thrust load-bearing surface 166 and second thrust load-bearing surface 168 when second fluid stream 160 is supplied to the second fluid bearing.

When second fluid stream 160 is supplied to second fluid gap 164, a fluid pressure may develop therein. This fluid pressure may provide a motive force that may resist contact between first thrust load-bearing surface 166 and second thrust load-bearing surface 168, and a magnitude of the motive force may be proportional to the fluid pressure, the surface area of the first thrust load-bearing surface, and/or the surface area of the second thrust load-bearing surface. Thus, it is within the scope of the present disclosure that first thrust load-bearing surface 166 and/or second thrust load-bearing surface 168 may be sized to prevent contact therebetween when second fluid stream 160 is provided to second fluid gap 164 and a magnitude of thrust load 156 is less than a threshold thrust load.

Additionally or alternatively, second bearing 150 may be configured to permit rotation of upper section 120 relative to lower section 110 about rotational axis 102 when the second fluid stream is provided to the second fluid gap. This is illustrated in FIG. 3, in which second fluid gap 164 is present between the first thrust load-bearing surface and the second thrust load-bearing surface. When first bearing 130 is first fluid bearing 134, and when first fluid gap 144 and second fluid gap 164 both are present within rotational positioning assembly 100, upper section 120 may be spaced apart from lower section 110, may not be in mechanical contact with lower section 110, may not be in direct mechanical contact with lower section 110, and/or may not be in indirect mechanical contact with lower section 110, as illustrated in FIG. 3.

It is within the scope of the present disclosure that at least a portion of first thrust load-bearing surface 166 may be configured to contact, mechanically contact, and/or physically contact at least a portion of second thrust load-bearing surface 168 when second fluid stream 160 is not provided to second fluid distribution manifold 158 (or the fluid pressure is not developed or otherwise present or maintained therein). This contact may produce a frictional force that may resist rotation of upper section 120 relative to lower section 110 about rotational axis 102. This is illustrated in FIG. 4, in which second fluid gap 164 is not present between the first thrust load-bearing surface and the second thrust load-bearing surface.

Additionally or alternatively, and as discussed herein with reference to FIG. 1, a vacuum may be selectively applied to second fluid inlet 162. This vacuum further may decrease the pressure between first thrust load-bearing surface 166 and second thrust load-bearing surface 168, increasing the frictional force therebetween, and further increasing the resistance to motion of upper section 120 relative to lower section 110.

It is within the scope of the present disclosure that first bearing 130 and/or second bearing 150 may be configured to permit at least limited translation of upper section 120 relative to lower section 110 along rotational axis 102. This translation may permit rotational positioning assembly 100 to transition between the configuration that is illustrated in FIG. 3 and the configuration that is illustrated in FIG. 4 without deformation of the rotational positioning assembly and/or application of a thrust load to first bearing 130.

It is within the scope of the present disclosure that first fluid stream 140 and/or second fluid stream 160 may include any suitable fluid stream that may be provided to first fluid gap 144 and/or second fluid gap 164, respectively. Illustrative, non-exclusive examples of first fluid stream 140 and/or of second fluid stream 160 are discussed herein with reference to fluid stream 182 of FIG. 1.

As discussed, FIG. 5 is a less schematic cross-sectional view of illustrative, non-exclusive examples of a rotational positioning assembly 100 according to the present disclosure, while FIG. 6 is a more detailed view of a portion of rotational positioning assembly 100 of FIG. 5 that is indicated therein at 70. In addition, FIG. 7 is a top view of the rotational positioning assembly of FIG. 5. In FIGS. 5-7, second fluid distribution manifold 158 is illustrated as including a plurality of fluid conduits 170 that extend within upper section 120. The plurality of fluid conduits 170 are defined by a plurality of radially extending fluid channels 172, which extend within upper section 120, and a plurality of bearing conduits 174, which extend between each of the plurality of radially extending fluid channels 172 and second fluid gap 164 (as perhaps best seen in FIG. 6).

It is within the scope of the present disclosure that the plurality of radially extending fluid channels may include any suitable number of radially extending fluid channels, including at least 2, at least 4, at least 6, at least 8, at least 10, at least 15, at least 20, at least 25, or at least 30 radially extending fluid channels. Similarly, it is also within the scope of the present disclosure that at least 2, at least 3, at least 4, at least 5, at least 6, at least 8, at least 10, at least 15, or at least 20 bearing conduits may extend between each of the plurality of radially extending fluid channels and the second fluid gap.

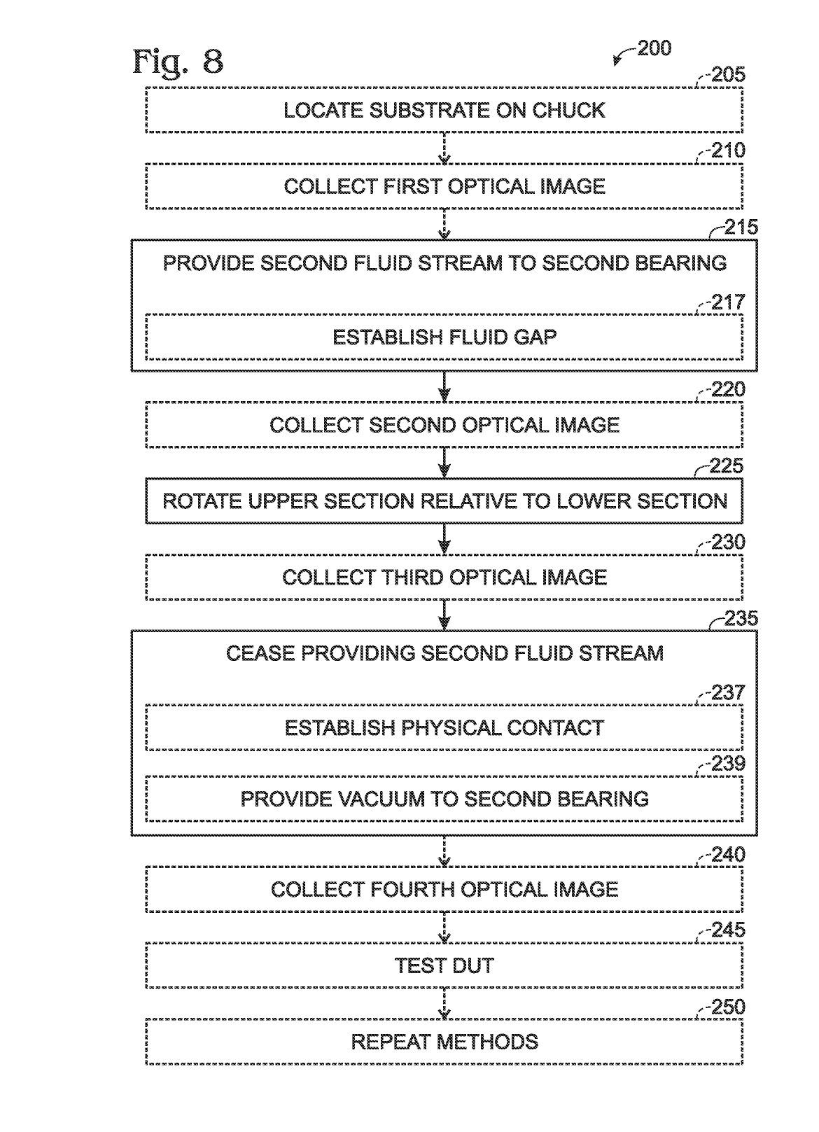

FIG. 8 is a flowchart depicting methods 200 according to the present disclosure of rotating a chuck within a probe system, such as probe system 20 of FIGS. 1-7. The probe system includes a rotational positioning assembly (such as a rotational positioning assembly 100) that includes a first bearing that is configured to support a radial load between an upper section of the rotational positioning assembly and a lower section of the rotational positioning assembly. The rotational positioning assembly further includes a second bearing that includes a fluid bearing and is configured to support a thrust load between the upper section and the lower section. The chuck is operatively attached to the upper section of the rotational positioning assembly and therefore rotates with rotation of the upper section.

Methods 200 may include collecting a first optical image at 210 and include providing a second fluid stream to a second bearing of the rotational positioning assembly at 215. Methods 200 further may include collecting a second optical image at 220 and include rotating the upper section relative to the lower section at 225. Methods 200 further may include collecting a third optical image at 230, include ceasing the providing the second fluid stream to the second bearing at 235, and may include collecting a fourth optical image at 240.

Collecting the first optical image at 210 may include collecting any suitable optical image with any suitable imaging device, such as imaging device 60 of FIG. 1. As an illustrative, non-exclusive example, the chuck may support a substrate that includes a device under test (DUT), and the collecting at 210 may include collecting an optical image of the DUT, of a selected portion of the DUT, and/or of a first selected portion of the DUT. It is within the scope of the present disclosure that the collecting at 210 may be performed at any suitable time during methods 200. As illustrative, non-exclusive examples, the collecting at 210 may be performed prior to the providing at 215, prior to the collecting at 220, prior to the rotating at 225, prior to the collecting at 230, prior to the ceasing at 235, and/or prior to the collecting at 240.

Providing the second fluid stream at 215 may include providing the second fluid stream to the second bearing to permit rotation of the upper section relative to the lower section. As an illustrative, non-exclusive example, the providing at 215 may include establishing, at 217, a second fluid gap between a first thrust load-bearing surface that is defined by the lower section and a second thrust load-bearing surface that is defined by the upper section. As another illustrative, non-exclusive example, the providing at 215 further may include generating a fluid pressure within the second fluid gap, with this fluid pressure providing a motive force that resists contact between the first thrust load-bearing surface and the second thrust load-bearing surface.

Collecting the second optical image at 220 may include collecting any suitable second optical image with the imaging device and may be performed at any suitable time and/or with any suitable sequence within methods 200. As illustrative, non-exclusive examples, the collecting at 220 may be performed subsequent to the collecting at 210, subsequent to the providing at 215, prior to the rotating at 225, prior to the collecting at 230, prior to the ceasing at 235, and/or prior to the collecting at 240.

The collecting at 220 may include collecting the second optical image of the first selected portion of the DUT. The collecting at 220 further may include translating the DUT into a focal plane of the imaging device to permit the collecting at 220. This may include translating with a translational positioning assembly, such as translational positioning assembly 50 of FIG. 1. As an illustrative, non-exclusive example, the establishing at 217 may include translating the upper section away from the lower section, thereby translating the first selected portion of the DUT out of the focal plane of the imaging device.

As another illustrative, non-exclusive example, the establishing at 217 may include translating the first selected portion of the DUT toward the imaging device, and the collecting at 220 may include translating the first selected portion of the DUT away from the imaging device to permit the collecting at 220. This may include translating by a width of the second fluid gap that is created during the establishing at 217. As another illustrative, non-exclusive example, the collecting at 220 also may include translating the first selected portion of the DUT transverse to an optical axis of the imaging device, such as optical axis 62 of FIG. 1, to bring the first selected portion of the DUT into a field of view of the imaging device and/or to permit the collecting at 220.

It is within the scope of the present disclosure that the collecting at 220 may be performed automatically, without user intervention, and/or under the control of a control system. As an illustrative, non-exclusive example, the collecting at 220 may include automatically translating the first selected portion of the DUT into the focal plane of the imaging device and/or automatically collecting the second image.

As another illustrative, non-exclusive example, the collecting at 220 further may include determining a first spatial offset for the first selected portion of the DUT. The first spatial offset may correlate a position of the first selected portion of the DUT prior to the establishing at 217 to a position of the first selected portion of the DUT subsequent to the establishing at 217, and the automatically translating may include automatically translating by the first spatial offset.

Rotating the upper section relative to the lower section at 225 may include rotating the upper section relative to the lower section by any suitable angle and/or with any suitable angular resolution. As illustrative, non-exclusive examples, the rotating at 225 may include rotating with an angular resolution of less than 0.0001 radians, less than 0.00008 radians, less than 0.00006 radians, less than 0.00005 radians, less than 0.00004 radians, less than 0.00003 radians, less than 0.00002 radians, less than 0.00001 radians, or less than 0.000005 radians.

Collecting the third optical image at 230 may include collecting any suitable third optical image with the imaging device and may be performed at any suitable time and/or with any suitable sequence within methods 200. As illustrative, non-exclusive examples, the collecting at 230 may be performed subsequent to the collecting at 210, subsequent to the providing at 215, subsequent to the collecting at 220, subsequent to the rotating at 225, prior to the ceasing at 235, and/or prior to the collecting at 240. As an illustrative, non-exclusive example, the collecting at 230 may include collecting the third optical image of a second selected portion of the DUT. The second selected portion of the DUT may be at least partially different and/or spaced apart from the first selected portion of the DUT. Additionally or alternatively, the second selected portion of the DUT may be at least partially, or even completely, coextensive with the first selected portion of the DUT.

Ceasing the providing the second fluid stream to the second bearing, at 235, may include ceasing the providing to restrict rotation of the upper section relative to the lower section. As an illustrative, non-exclusive example, the ceasing at 235 further may include establishing, at 237, physical contact between at least a portion of the first thrust load-bearing surface and at least a portion of the second thrust load-bearing surface. This may generate and/or increase a frictional force between the first thrust load-bearing surface and the second thrust load-bearing surface, thereby increasing a resistance to relative motion therebetween. As another illustrative, non-exclusive example, the ceasing at 235 also may include providing a vacuum to the second bearing at 239. Providing the vacuum at 239 may decrease the pressure between the first thrust load-bearing surface and the second thrust load-bearing surface, which may increase a contact force therebetween. Accordingly, this may thereby increase the frictional force and increase the resistance to relative motion between the first thrust load-bearing surface and the second thrust load-bearing surface.

Collecting the fourth optical image at 240 may include collecting any suitable fourth optical image with the imaging device and may be performed at any suitable time and/or with any suitable sequence within methods 200. As illustrative, non-exclusive examples, the collecting at 240 may be performed subsequent to the collecting at 210, subsequent to the providing at 215, subsequent to the collecting at 220, subsequent to the rotating at 225, subsequent to the collecting at 230, and/or subsequent to the ceasing at 235.

The collecting at 240 may include collecting the fourth optical image of the second selected portion of the DUT. The collecting at 240 further may include translating the DUT into a focal plane of the imaging device to permit the collecting at 240. This may include translating with the translational positioning assembly. As an illustrative, non-exclusive example, the ceasing at 235 may include translating the upper section toward the lower section, thereby translating the second selected portion of the DUT out of the focal plane of the imaging device.

As another illustrative, non-exclusive example, the ceasing at 235 may include translating the second selected portion of the DUT away from the imaging device, and the collecting at 240 may include translating the second selected portion of the DUT toward the imaging device to permit the collecting at 240. This may include translating by the width of the second fluid gap. As another illustrative, non-exclusive example, the collecting at 240 also may include translating the second selected portion of the DUT transverse to the optical axis of the imaging device to bring the second selected portion of the DUT into the field of view of the imaging device and/or to permit the collecting at 240.

It is within the scope of the present disclosure that the collecting at 240 may be performed automatically, without user intervention, and/or under the control of a control system. As an illustrative, non-exclusive example, the collecting at 240 may include automatically translating the second selected portion of the DUT into the focal plane of the imaging device and/or automatically collecting the fourth optical image.

As another illustrative, non-exclusive example, the collecting at 240 further may include determining a second spatial offset for the second selected portion of the DUT. The second spatial offset may correlate a position of the second selected portion of the DUT prior to the ceasing at 235 to a position of the second selected portion of the DUT subsequent to the ceasing at 235, and the automatically translating may include automatically translating by the second spatial offset.

As illustrated in dashed lines in FIG. 8, methods 200 further may include locating the substrate on the chuck at 205, testing the DUT at 245, and/or repeating at least a portion of the methods at 250. When methods 200 include at least the testing at 245, methods 200 also may be referred to herein as methods 200 of testing the DUT.

The locating at 205 may include locating the substrate on the chuck in any suitable manner. As an illustrative, non-exclusive example, the locating at 205 may include transferring the substrate, such as with a transfer robot, to the chuck and/or to an upper surface of the chuck. Additionally or alternatively, the locating at 205 also may include placing the substrate on the upper surface of the chuck.

Testing the DUT at 245 may include testing the DUT in any suitable manner. As an illustrative, non-exclusive example, the testing at 245 may include contacting the DUT with a probe tip, such as probe tip 42 of FIG. 1. As another illustrative, non-exclusive example, the testing at 245 may include providing a test signal, such as test signal 93 of FIG. 1, to the DUT. As yet another illustrative, non-exclusive example, the testing at 245 may include receiving a resultant signal, such as resultant signal 96 of FIG. 1, from the DUT.

Repeating the methods at 250 may include repeating any suitable portion of the methods. As an illustrative, non-exclusive example, the substrate may include and/or be a first substrate and the repeating at 250 may include removing the first substrate from the chuck and locating a second substrate on the chuck. The repeating at 250 further may include rotating the second substrate, such as via the providing at 215, the rotating at 225, and the ceasing at 235. The repeating at 250 also may include testing a DUT that is preset on the second substrate, such as via the testing at 245.

In the present disclosure, several of the illustrative, non-exclusive examples have been discussed and/or presented in the context of flow diagrams, or flow charts, in which the methods are shown and described as a series of blocks, or steps. Unless specifically set forth in the accompanying description, it is within the scope of the present disclosure that the order of the blocks may vary from the illustrated order in the flow diagram, including with two or more of the blocks (or steps) occurring in a different order and/or concurrently. It also is within the scope of the present disclosure that the blocks, or steps, may be implemented as logic, which also may be described as implementing the blocks, or steps, as logics. In some applications, the blocks, or steps, may represent expressions and/or actions to be performed by functionally equivalent circuits or other logic devices. The illustrated blocks may, but are not required to, represent executable instructions that cause a computer, processor, and/or other logic device to respond, to perform an action, to change states, to generate an output or display, and/or to make decisions.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entity in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” may mean A alone, B alone, C alone, A and B together, A and C together, B and C together, A, B and C together, and optionally any of the above in combination with at least one other entity.

In the event that any patents, patent applications, or other references are incorporated by reference herein and define a term in a manner or are otherwise inconsistent with either the non-incorporated portion of the present disclosure or with any of the other incorporated references, the non-incorporated portion of the present disclosure shall control, and the term or incorporated disclosure therein shall only control with respect to the reference in which the term is defined and/or the incorporated disclosure was originally present.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It also is within the scope of the present disclosure that elements, components, and/or other recited subject matter that is recited as being adapted to perform a particular function may additionally or alternatively be described as being configured to perform that function, and vice versa.

Illustrative, non-exclusive examples of systems and methods according to the present disclosure are presented in the following enumerated paragraphs. It is within the scope of the present disclosure that an individual step of a method recited herein, including in the following enumerated paragraphs, may additionally or alternatively be referred to as a “step for” performing the recited action.

A1. A rotational positioning assembly, comprising:

a lower section;

an upper section that is configured to selectively rotate relative to the lower section about a rotational axis;

a first bearing that is configured to support a radial load between the upper section and the lower section when the upper section rotates relative to the lower section; and

a second bearing that is configured to support a thrust load between the upper section and the lower section when the upper section rotates relative to the lower section.

A2. The assembly of paragraph A1, wherein the first bearing is configured to permit translation of the upper section relative to the lower section along the rotational axis.

A3. The assembly of any of paragraphs A1-A2, wherein the first bearing includes, and optionally is, at least one of a rotary bearing, a rolling bearing, and a rolling element bearing.

A4. The assembly of any of paragraphs A1-A3, wherein the first bearing includes at least one of:

(i) a plurality of rolling elements;

(ii) a plurality of ball bearings; and

(iii) a plurality of roller bearings.

A5. The assembly of any of paragraphs A1-A4, wherein the first bearing is operatively attached the lower section and to the upper section.

A6. The assembly of any of paragraphs A1-A5, wherein the first bearing includes, and optionally is, at least one of a first fluid bearing, a first hydrostatic bearing, and a first air bearing.

A7. The assembly of paragraph A6, wherein the first bearing is defined by a first radial load-bearing surface and a second radial load-bearing surface, optionally wherein the lower section defines the first radial load-bearing surface, and further optionally wherein the upper section defines the second radial load-bearing surface.

A8. The assembly of paragraph A7, wherein the assembly further includes a first fluid distribution manifold that is configured to provide, and optionally selectively provide, a first fluid stream to a first fluid gap of the first bearing, wherein the first fluid gap is defined between the first radial load-bearing surface and the second radial load-bearing surface at least when the first fluid stream is supplied to the first fluid gap.

A9. The assembly of paragraph A8, wherein the first radial load-bearing surface and the second radial load-bearing surface are sized to prevent contact therebetween when the first fluid stream is provided to the first fluid gap and the radial load is less than a threshold radial load.

A10. The assembly of any of paragraphs A8-A9, wherein, when the first fluid stream is supplied to the first fluid gap, the assembly further includes the first fluid gap.

A11. The assembly of any of paragraphs A1-A10, wherein the second bearing includes, and optionally is, at least one of a second fluid bearing, a second hydrostatic bearing, and a second air bearing.

A12. The assembly of paragraph A11, wherein the second bearing is defined by a first thrust load-bearing surface and a second thrust load-bearing surface, optionally wherein the lower section defines the first thrust load-bearing surface, and further optionally wherein the upper section defines the second thrust load-bearing surface.

A13. The assembly of paragraph A12, wherein the assembly further includes a second fluid distribution manifold that is configured to selectively provide a second fluid stream to a second fluid gap of the second bearing, wherein the second fluid gap is defined between the first thrust load-bearing surface and the second thrust load-bearing surface at least when the second fluid stream is supplied to the second fluid gap.

A14. The assembly of paragraph A13 when dependent from paragraph A8, wherein the assembly includes the first fluid stream and the second fluid stream, wherein the first fluid stream is supplied to the first gap, wherein the second fluid stream is supplied to the second gap, and further wherein the upper section is at least one of spaced apart from the lower section and not in mechanical contact with the lower section.

A15. The assembly of any of paragraphs A13-A14, wherein the first thrust load-bearing surface and the second thrust load-bearing surface are sized to prevent contact therebetween when the second fluid stream is provided to the second fluid gap and the thrust load is less than a threshold thrust load.

A16. The assembly of any of paragraphs A13-A15, wherein the second bearing is configured to permit rotation of the upper section relative to the lower section about the rotational axis when the second fluid stream is provided to the second fluid gap.

A17. The assembly of any of paragraphs A13-A16, wherein the assembly further includes a second fluid source that is configured to provide the second fluid stream.

A18. The assembly of any of paragraphs A13-A16, wherein the second fluid distribution manifold is further configured to selectively provide a vacuum to the second bearing, wherein at least a portion of the first thrust load-bearing surface is configured to contact at least a portion of the second thrust load-bearing surface when the vacuum is provided to the second bearing.

A19. The assembly of paragraph A18, wherein the second bearing is configured to resist rotation of the upper section relative to the lower section about the rotational axis when the vacuum is provided to the second bearing.

A20. The assembly of any of paragraphs A13-A19, wherein the second fluid distribution manifold is defined by at least one, and optionally only one, of the lower section and the upper section.

A21. The assembly of any of paragraphs A13-A20, wherein the second fluid distribution manifold includes a plurality of fluid conduits and a fluid inlet, wherein the plurality of fluid conduits is configured to convey the second fluid stream between the fluid inlet and the second fluid gap.

A22. The assembly of paragraph A21, wherein the plurality of fluid conduits are defined by a plurality of radially extending fluid channels, and optionally wherein the plurality of radially extending fluid channels includes at least 2, at least 4, at least 6, at least 8, at least 10, at least 15, at least 20, at least 25, or at least 30 fluid channels.

A23. The assembly of paragraph A22, wherein the plurality of fluid conduits are further defined by a plurality of bearing conduits, wherein a subset of the plurality of bearing conduits extends between each of the plurality of radially extending fluid channels and the second fluid gap, and optionally wherein the subset of the plurality of bearing conduits includes at least 2, at least 3, at least 4, at least 5, at least 6, at least 8, at least 10, at least 15, or at least 20 bearing conduits.

A24. The assembly of any of paragraphs A13-A23, wherein, when the second fluid stream is supplied to the second fluid gap, the assembly further includes the second fluid gap.

A25. The assembly of any of paragraphs A13-A24, wherein the second bearing is configured to permit translation of the upper section relative to the lower section along the rotational axis.

A26. The assembly of any of paragraphs A12-A25 when dependent from paragraph A7, wherein the first thrust load-bearing surface is at least substantially, and optionally is, perpendicular to the first radial load-bearing surface.

A27. The assembly of any of paragraphs A12-A26 when dependent from paragraph A7, wherein the second thrust load-bearing surface is at least substantially, and optionally is, perpendicular to the second radial load-bearing surface.

A28. The assembly of any of paragraphs A1-A27, wherein the second bearing is not a rotary bearing, a rolling bearing, or a rolling element bearing.

A29. The assembly of any of paragraphs A1-A28, wherein the assembly further includes a rotational drive that is configured to selectively provide a motive force for rotation of the upper section relative to the lower section.

A30. The assembly of any of paragraphs A1-A29, wherein the radial load is at least substantially, and optionally is, perpendicular to the thrust load.

A31. A chuck that is configured to support a device under test, the chuck comprising:

a chuck body that defines a lower surface and an upper surface that is configured to support, and optionally contact, the device under test; and

the assembly of any of paragraphs A1-A30, wherein the upper section of the assembly is in mechanical communication with, and optionally operatively attached to, the lower surface of the chuck body.

A32. A probe system that is configured to probe a device under test, the probe system comprising:

a probe tip that is configured to electrically contact the device under test; and

the chuck of paragraph A31.

A33. The probe system of paragraph A32, wherein the probe system further includes an enclosure that is configured to at least one of electrically, optically, fluidly, and electromagnetically isolate the device under test from an ambient environment.

A34. The probe system of any of paragraphs A32-A33, wherein the probe tip forms a portion of a probe card, and further wherein the system includes the probe card.

A35. The probe system of any of paragraphs A32-A34, wherein the probe system further includes a signal generation assembly that is configured to provide a test signal to the device under test.

A36. The probe system of any of paragraphs A32-A35, wherein the probe system further includes a signal analysis assembly that is configured to receive a resultant signal from the device under test.

A37. The probe system of any of paragraphs A32-A36, wherein the probe system further includes an imaging device that is configured to collect an optical image of the device under test.

A38. The probe system of any of paragraphs A32-A37, wherein the probe system further includes a translational positioning assembly that is configured to translate the probe tip and the chuck relative to one another, optionally wherein the translational positioning assembly is configured to translate the chuck relative to the probe tip, and further optionally wherein the translational positioning assembly is configured to translate the probe tip relative to the chuck.

A39. The probe system of any of paragraphs A32-A38, wherein the probe system further includes a control system that is programmed to control the operation of at least a portion of the probe system.

A40. The probe system of paragraph A39, wherein the control system is programmed to perform the method of any of paragraphs B1-B28.

B1. A method of rotating a chuck within a probe system, wherein the probe system includes a rotational positioning assembly that includes a first bearing, which is configured to support a radial load between an upper section of the rotational positioning assembly and a lower section of the rotational positioning assembly, wherein the rotational positioning assembly further includes a second bearing, which is a fluid bearing and is configured to support a thrust load between the upper section and the lower section, and further wherein the chuck is operatively attached to the upper section of the rotational assembly, the method comprising:

providing a second fluid stream to the second bearing to permit rotation of the upper section relative to the lower section;

rotating the upper section relative to the lower section; and

ceasing the providing the second fluid stream to the second bearing to restrict rotation of the upper section relative to the lower section.

B2. A method of rotating a chuck within a probe system, wherein the chuck includes the chuck of paragraph A31 and/or wherein the probe system includes the probe system of any of paragraphs A32-A40, the method comprising:

providing a/the second fluid stream to the second bearing to permit rotation of the upper section relative to the lower section;

rotating the upper section relative to the lower section; and

ceasing the providing the second fluid stream to the second bearing to restrict rotation of the upper section relative to the lower section.

B3. The method of any of paragraphs B1-B2, wherein the second bearing is defined by a/the first thrust load-bearing surface and a/the second thrust load-bearing surface, optionally wherein the lower section defines the first thrust load-bearing surface, and further optionally wherein the upper section defines the second thrust load-bearing surface.

B4. The method of paragraph B3, further wherein the providing the second fluid stream includes establishing a/the second fluid gap between the first thrust load-bearing surface and the second thrust load-bearing surface.

B5. The method of any of paragraphs B3-B4, wherein the method further includes providing a vacuum to the second bearing.

B6. The method of any of paragraphs B1-B5, wherein the ceasing includes establishing physical contact between at least a portion of the first thrust load-bearing surface and at least a portion of the second thrust load-bearing surface.

B7. The method of any of paragraphs B1-B6, wherein the chuck supports a DUT, and further wherein the method includes collecting an optical image of the DUT with an imaging device.

B8. The method of paragraph B7, wherein the collecting includes collecting a first optical image of a first selected portion of the DUT prior to the providing the second fluid stream.

B9. The method of paragraph B8, wherein the collecting further includes collecting a second optical image of the first selected portion of the DUT subsequent to the providing the second fluid stream and prior to the rotating.

B10. The method of paragraph B9 when dependent from paragraph B4, wherein the probe system further includes a translational positioning assembly that is configured to translate the DUT and the imaging device relative to one another, wherein the establishing the second fluid gap includes translating the upper section away from the lower section thereby translating the first selected portion of the DUT out of a focal plane of the imaging device, and further wherein the method includes translating the first selected portion of the DUT into the focal plane of the imaging device with the translational positioning assembly to permit the collecting the second optical image of the first selected portion of the DUT.

B11. The method of paragraph B10, wherein the translating the first selected portion of the DUT includes translating the DUT away from the imaging device, optionally by a width of the second fluid gap.

B12. The method of any of paragraphs B10-B11, wherein the translating the first selected portion of the DUT includes translating the DUT transverse to an optical axis of the imaging device.

B13. The method of any of paragraphs B10-B12, wherein the translating the first selected portion of the DUT includes automatically translating the first selected portion of the DUT responsive to the establishing the second fluid gap.

B14. The method of paragraph B13, wherein the method further includes determining a first spatial offset for the first selected portion of the DUT that correlates a position of the first selected portion of the DUT prior to the establishing the second fluid gap to a position of the first selected portion of the DUT subsequent to the establishing the second fluid gap, and further wherein the automatically translating the first selected portion of the DUT includes translating by the first spatial offset.

B15. The method of any of paragraphs B7-B14, wherein the collecting further includes collecting a third optical image of a second selected portion of the DUT subsequent to the rotating and prior to the ceasing.

B16. The method of paragraph B15, wherein the collecting further includes collecting a fourth optical image of the second selected portion of the DUT subsequent to the ceasing.

B17. The method of paragraph B16, wherein the probe system further includes a/the translational positioning assembly that is configured to translate the DUT and the imaging device relative to one another, wherein the ceasing includes translating the upper section toward the lower section thereby translating the second selected portion of the DUT out of a/the focal plane of the imaging device, and further wherein the method includes translating the second selected portion of the DUT into the focal plane of the imaging device with the translational positioning assembly to permit the collecting the third optical image of the second selected portion of the DUT.

B18. The method of paragraph B17, wherein the translating the second selected portion of the DUT includes translating the DUT toward the imaging device, optionally by a/the width of a/the second fluid gap.

B19. The method of any of paragraphs B17-B18, wherein the translating the second selected portion of the DUT includes translating the DUT transverse to an/the optical axis of the imaging device.

B20. The method of any of paragraphs B17-B19, wherein the translating the second selected portion of the DUT includes automatically translating the second selected portion of the DUT responsive to the ceasing.

B21. The method of paragraph B20, wherein the method further includes determining a second spatial offset for the second selected portion of the DUT that correlates a position of the second selected portion of the DUT prior to the ceasing to a position of the second selected portion of the DUT subsequent to the ceasing, and further wherein the automatically translating the second selected portion of the DUT includes translating by the second spatial offset.

B22. A method of testing a device under test (DUT) with a probe system, wherein the DUT is present on a substrate, wherein the probe system includes a rotational positioning assembly that includes a first bearing, which is configured to support a radial load between an upper section of the rotational positioning assembly and a lower section of the rotational positioning assembly, wherein the rotational positioning assembly further includes a second bearing, which is a fluid bearing and is configured to support a thrust load between the upper section and the lower section, wherein the chuck is operatively attached to the upper section of the rotational assembly, and further wherein the probe system includes a probe tip that is configured to contact the DUT, the method comprising:

locating the substrate on an upper surface of the chuck;

rotating the chuck to operatively align the DUT with the probe tip, wherein the rotating includes rotating using the method of any of paragraphs B1-B21; and

testing the DUT.

B23. The method of paragraph B22, wherein the locating includes transferring the substrate to the upper surface of the chuck with a transfer robot.

B24. The method of any of paragraphs B22-B23, wherein the testing includes contacting the DUT with the probe tip.

B25. The method of any of paragraphs B22-B24, wherein the testing includes providing a test signal to the DUT.

B26. The method of any of paragraphs B22-B25, wherein the testing includes receiving a resultant signal from the DUT.

B27. The method of any of paragraphs B22-B26, wherein, subsequent to the testing, the method further includes removing the substrate from the upper surface of the chuck.

B28. The method of paragraph B27, wherein the DUT is a first DUT, wherein the substrate is a first substrate, and further wherein the method includes repeating at least the locating, the rotating, and the testing to locate a second substrate on the upper surface of the chuck, rotate the chuck to operatively align a second DUT of the second substrate with the probe tip, and test the second DUT.

### INDUSTRIAL APPLICABILITY

The systems and methods disclosed herein are applicable to the electronic device development, manufacturing, and test industries.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. A chuck configured to support a device under test, the chuck comprising:
a chuck body that defines a lower surface and an upper surface that is configured to support the device under test; and
a rotational positioning assembly, comprising:
(i) a lower section;
(ii) an upper section that is configured to selectively rotate relative to the lower section about a rotational axis, wherein the upper section is in mechanical communication with the lower surface of the chuck body;
(iii) a first bearing that is configured to support a radial load between the upper section and the lower section when the upper section rotates relative to the lower section; and
(iv) a second bearing that is configured to support a thrust load between the upper section and the lower section when the upper section rotates relative to the lower section.

2. The chuck of claim 1, wherein the first bearing is configured to permit translation of the upper section relative to the lower section along the rotational axis.

3. The chuck of claim 1, wherein the first bearing includes at least one of a rotary bearing, a rolling bearing, and a rolling element bearing.

4. The chuck of claim 1, wherein the first bearing is operatively attached the lower section and to the upper section.

5. The chuck of claim 1, wherein the first bearing includes at least one of a first fluid bearing, a first hydrostatic bearing, and a first air bearing.

6. The chuck of claim 5, wherein the first bearing is defined by a first radial load-bearing surface and a second radial load-bearing surface, and further wherein the chuck includes a first fluid distribution manifold that is configured to provide a first fluid stream to a first fluid gap of the first bearing, wherein the first fluid gap is defined between the first radial load-bearing surface and the second radial load-bearing surface at least when the first fluid stream is supplied to the first fluid gap.

7. The chuck of claim 1, wherein the second bearing includes at least one of a second fluid bearing, a second hydrostatic bearing, and a second air bearing.

8. The chuck of claim 7, wherein the second bearing is defined by a first thrust load-bearing surface and a second thrust load-bearing surface.

9. The chuck of claim 8, wherein the chuck further includes a second fluid distribution manifold that is configured to selectively provide a second fluid stream to a second fluid gap of the second bearing, wherein the second fluid gap is defined between the first thrust load-bearing surface and the second thrust load-bearing surface at least when the second fluid stream is supplied to the second fluid gap.

10. The chuck of claim 9, wherein the second bearing is configured to permit rotation of the upper section relative to the lower section about the rotational axis when the second fluid stream is provided to the second fluid gap.

11. The chuck of claim 9, wherein the second fluid distribution manifold is further configured to selectively provide a vacuum to the second bearing, wherein at least a portion of the first thrust load-bearing surface is configured to contact at least a portion of the second thrust load-bearing surface when the vacuum is provided to the second bearing, and further wherein the second bearing is configured to resist rotation of the upper section relative to the lower section about the rotational axis when the vacuum is provided to the second bearing.

12. The chuck of claim 9, wherein the second bearing is configured to permit translation of the upper section relative to the lower section along the rotational axis.

13. The chuck of claim 1, wherein the chuck further includes a rotational drive that is configured to selectively provide a motive force for rotation of the upper section relative to the lower section.

14. A probe system configured to probe a device under test, the probe system comprising:
a probe tip configured to electrically contact the device under test; and
the chuck of claim 1.

15. The probe system of claim 14, wherein the probe system further includes:
an enclosure that is configured to at least one of electrically, optically, fluidly, and electromagnetically isolate the device under test from an ambient environment;
a probe card that includes the probe tip;
a signal generation assembly that is configured to provide a test signal to the device under test; and
a signal analysis assembly that is configured to receive a resultant signal from the device under test.

16. A method of rotating a chuck within the probe system of claim 14, the method comprising:
providing a fluid stream to the second bearing to permit rotation of the upper section relative to the lower section;
rotating the upper section relative to the lower section; and
ceasing the providing the fluid stream to the second bearing to restrict rotation of the upper section relative to the lower section.

17. A method of rotating a chuck within a probe system, wherein the probe system includes a rotational positioning assembly that includes a first bearing, which is configured to support a radial load between an upper section of the rotational positioning assembly and a lower section of the rotational positioning assembly, wherein the rotational positioning assembly further includes a second bearing, which is a fluid bearing and is configured to support a thrust load between the upper section and the lower section, and further wherein the chuck is operatively attached to the upper section of the rotational assembly, the method comprising:
providing a fluid stream to the second bearing to permit rotation of the upper section relative to the lower section;
rotating the upper section relative to the lower section; and
ceasing the providing the fluid stream to the second bearing to restrict rotation of the upper section relative to the lower section.

18. The method of claim 17, wherein the second bearing is defined by a first thrust load-bearing surface and a second thrust load-bearing surface, and further wherein the providing the fluid stream includes establishing a fluid gap between the first thrust load-bearing surface and the second thrust load-bearing surface.

19. The method of claim 18, wherein the ceasing includes establishing physical contact between at least a portion of the first thrust load-bearing surface and at least a portion of the second thrust load-bearing surface.

20. A method of testing a device under test (DUT) with a probe system, wherein the DUT is present on a substrate, wherein the probe system includes a rotational positioning assembly that includes a first bearing, which is configured to support a radial load between an upper section of the rotational positioning assembly and a lower section of the rotational positioning assembly, wherein the rotational positioning assembly further includes a second bearing, which is a fluid bearing and is configured to support a thrust load between the upper section and the lower section, wherein the chuck is operatively attached to the upper section of the rotational assembly, and further wherein the probe system includes a probe tip that is configured to contact the DUT, the method comprising:
locating the substrate on an upper surface of the chuck;
rotating the chuck to operatively align the DUT with the probe tip, wherein the rotating includes rotating using the method of claim 17; and
testing the DUT.

21. The method of claim 20, wherein the locating includes transferring the substrate to the upper surface of the chuck with a transfer robot.

22. The method of claim 20, wherein the testing includes:
contacting the DUT with the probe tip;
providing a test signal to the DUT; and
receiving a resultant signal from the DUT.

23. The method of claim 20, wherein, subsequent to the testing, the method further includes removing the substrate from the upper surface of the chuck.

24. The method of claim 23, wherein the DUT is a first DUT, wherein the substrate is a first substrate, and further wherein the method includes repeating at least the locating, the rotating, and the testing to locate a second substrate on the upper surface of the chuck, rotate the chuck to operatively align a second DUT of the second substrate with the probe tip, and test the second DUT.
